(19) United States
(12) Patent Application Publication
(10) Pub. No.: US 2024/0070224 A1
(43) Pub. Date: Feb. 29, 2024

(54) Method for identifying modal parameters of engineering structures based on fast stochastic subspace identification

(71) Applicants: Hohai University, Nanjing (CN); Jiangsu Dongjiao Intelligent Control Technology Group Co., Ltd, Nanjing (CN)

(72) Inventors: Maosen Cao, Nanjing (CN); Qingyang Wei, Nanjing (CN); Jie Wang, Nanjing (CN); Yufeng Zhang, Nanjing (CN); Xiangdong Qian, Nanjing (CN); Dragoslav Sumarac, Nanjing (CN); Emil Manoach, Nanjing (CN); Shuai Li, Nanjing (CN)

(21) Appl. No.: 18/366,659

(22) Filed: Aug. 7, 2023

(30) Foreign Application Priority Data
Aug. 22, 2022 (CN) 202211005306.7

(51) Int. Cl. G06F 17/16

(52) U.S. Cl. CPC G06F 17/16

(57) ABSTRACT

The present disclosure provides a method for identifying modal parameters of engineering structures based on fast stochastic subspace identification, and relates to the field of structural modal parameters identification. The method includes the following steps: collecting responses; obtaining a unitary matrix by performing random projection on and QR decomposition of a matrix; obtaining a small matrix by projecting a Toeplitz matrix onto the unitary matrix; obtaining U, S, V matrices respectively by performing singular value decomposition of the small matrix; performing eigenvalue decomposition; and determining an order interval. According to the present disclosure, the small matrix is obtained through performing random projection on and QR decomposition of the traditional Toeplitz matrix, the dimensionality of the matrix by singular value decomposition is reduced and the computational efficiency of the matrix is improved.

### CROSS-REFERENCE TO RELATED APPLICATIONS

This application claims priority of Chinese Patent Application No. 202211005306.7, filed on Aug. 22, 2022, the entire contents of which are incorporated herein by reference.

### TECHNICAL FIELD

The present disclosure relates to the technical field of structural modal parameters identification, and in particular, relates to a method for identifying modal parameters of engineering structures based on fast stochastic subspace identification.

### BACKGROUND

Modal parameters, including natural frequency, damping ratio and mode shapes, are basic parameters that reflect dynamic properties of structures and are of great significance for structural health monitoring. Currently, two main methods used to obtain the structural modal parameters are experimental modal analysis and operational modal analysis. The experimental modal analysis is generally performed based on a structural frequency response function, which requires both input and output information about the structures. In contrast, the operational modal analysis requires only the output information of the structures. Therefore, the operational modal analysis is more suitable for large and complicated structures and has feasibility to be implemented continuously. In view of operational modal analysis in different structures, there are a plurality of identification methods, including an eigensystem realization algorithm, an autoregression algorithm, a cross-power spectrum method and a stochastic subspace identification method, etc. Among those methods, the stochastic subspace identification method is a more advanced parameters identification method with good convergence and high precision.

However, the computational expense of the stochastic subspace identification method is higher, especially in the case of a large number of channels and a large number of rows of the Toeplitz matrix, a large amount of computational resources are required, and the computation speed is slow, which limits the large-scale application and online identification of this method.

### SUMMARY

To solve the above problems, a method for identifying modal parameters of engineering structures based on fast stochastic subspace identification is provided in the present disclosure to overcome the limitations of slow computation speed in traditional stochastic subspace identification methods.

To achieve the objective above, the present disclosure provides the following technical solutions:
a method for identifying modal parameters of engineering structures based on fast stochastic subspace identification includes the following steps:
collecting responses of engineering structures under ambient excitation; and constructing a past matrix and two future matrices according to the collected responses;
constructing two Toeplitz matrices in sequence according to the past matrix and the two future matrices;
obtaining a new matrix by performing random projection on the first Toeplitz matrix; and obtaining a unitary matrix by performing QR decomposition of the new matrix;
obtaining a small matrix by projecting the Toeplitz matrix onto the unitary matrix; and obtaining U, S, V matrices respectively by performing singular value decomposition of the small matrix;
calculating observation, output and state matrices of the engineering structures according to the U, S, V matrices and the latter Toeplitz matrix;
performing eigenvalue decomposition of the state matrix of the engineering structures, and obtaining the modal parameters through calculating according to results of the eigenvalue decomposition, as well as the observation and output matrices; and
determining an order interval of the engineering structures and calculating the modal parameters repeatedly to obtain the generated modal parameters in each order.

Preferably, the ambient excitation includes a load caused by the environment where the engineering structures are located; the responses of the engineering structures under the ambient excitation include acceleration, velocity or displacement.

Preferably, the constructing a past matrix and two future matrices according to the collected responses, respectively are:
the past matrix:

$${Y}_{p} = \frac{1}{\sqrt{j}} [ \begin{matrix}{y}_{0} & {y}_{1} & … & {y}_{j - 1} \\ {y}_{1} & {y}_{2} & … & {y}_{j} \\ ⋮ & ⋮ & ⋱ & ⋮ \\ {y}_{i - 1} & {y}_{i} & … & {y}_{i + j - 2}\end{matrix} ]$$

the future matrix 1:

$${Y}_{f 1} = \frac{1}{\sqrt{j}} [ \begin{matrix}{y}_{i} & {y}_{i + 1} & … & {y}_{i + j - 1} \\ {y}_{i + 1} & {y}_{i + 2} & … & {y}_{i + j} \\ ⋮ & ⋮ & ⋱ & ⋮ \\ {y}_{2 i - 1} & {y}_{2 i} & … & {y}_{2 i + j - 2}\end{matrix} ]$$

the future matrix 2:

$${Y}_{f 2} = \frac{1}{\sqrt{j}} [ \begin{matrix}{y}_{i + 1} & {y}_{i + 2} & … & {y}_{i + j} \\ {y}_{i + 2} & {y}_{i + 3} & … & {y}_{i + j + 1} \\ ⋮ & ⋮ & ⋱ & ⋮ \\ {y}_{2 i} & {y}_{2 i + 1} & … & {y}_{2 i + j - 1}\end{matrix} ]$$

where y represents the collected responses; i represents the number of rows of the three matrices; j represents the number of columns of the three matrices; and the size of j is not greater than the length of the collected responses.

Preferably, the constructing two Toeplitz matrices, respectively are:

Toeplitz matrix 1:

T_{1|i}=[Y_{f}Yₚ^{T}]

Toeplitz matrix 2:

T_{2|i+1}=[Y_{f2}Yₚ^{T}].

Preferably, the obtaining a new matrix by performing random projection on the first Toeplitz matrix is shown as the following formula:

Y=T_{1|i}Ω

where Y is the new matrix; Ω is an N-dimensional Gaussian random matrix; and N is the number of orders of the structures.

Preferably, the obtaining a unitary matrix by performing QR decomposition of the new matrix includes the following steps:

performing QR decomposition of the new matrix Y:

Y=QR

obtaining the unitary matrix Q according to the above formula; and

where the QR decomposition is carried out based on a Schmidt orthogonalization algorithm, a Givens algorithm or an Householder algorithm.

Preferably, the obtaining a small matrix by projecting Toeplitz matrix onto the unitary matrix is shown as the following formula:

B=Q^{T}T_{1|i}

where B represents small matrix;

the performing singular value decomposition of the small matrix is shown as follows:

B=U_{B}SV^{T}

B=QU_{B}

obtaining U, S, V matrices respectively according to the above formulas.

Preferably, the observation, output and state matrices of the engineering structures are shown as the following formulas:

O=U₁S₁^{1/2}

C=s₁^{1/2}v₁^{T}

A=s₁^{-1/2}u₁^{T}T_{2|i+1}v₁s₁^{-1/2}

where O represents the observation matrix of the structure, C represents the output matrix of the structure and A represents the state matrix of the structure; and U₁, S₁, V₁ are the first 1−N parts of the U, S, V matrices respectively.

Preferably, the performing eigenvalue decomposition of the state matrix of the engineering structures is shown as the following formula:

A=φRφ⁻¹

obtaining an eigenvector φ and a diagonal matrix R according to the above formula. Preferably, the calculating the modal parameters is shown as the following formulas:

λ_{S}^{C}=ln(λ_{S})/Δt

f_{S}=|λ_{S}^{C}|/2π

ξₛ=|Re(λ_{S}^{C})|/|λ_{S}^{C}|

ϕ=C_{ϕ}

where fₛ, ξ_{S} and ϕ are frequency, damping ratio and mode shapes in the Sₜₕ order of the engineering structures respectively; Re represents a real part; λS is the Sₜₕ value on the diagonal line in the diagonal matrix R; and Δt is sampling intervals of the responses.

Compared with the prior art, the present disclosure provides a method for identifying modal parameters of engineering structures based on fast stochastic subspace identification. The small matrix is obtained to replace the Toplitz matrix through randomly projecting and performing QR deposition of the traditional Toeplitz matrix, such that the dimensionality of the matrix through singular value decomposition is greatly reduced and the computational efficiency of the matrix is improved.

### BRIEF DESCRIPTION OF THE DRAWINGS

FIG. 1 is a flow diagram of a method according to the present disclosure; and

FIG. 2 is identification results of mode shapes according to an example of the present disclosure.

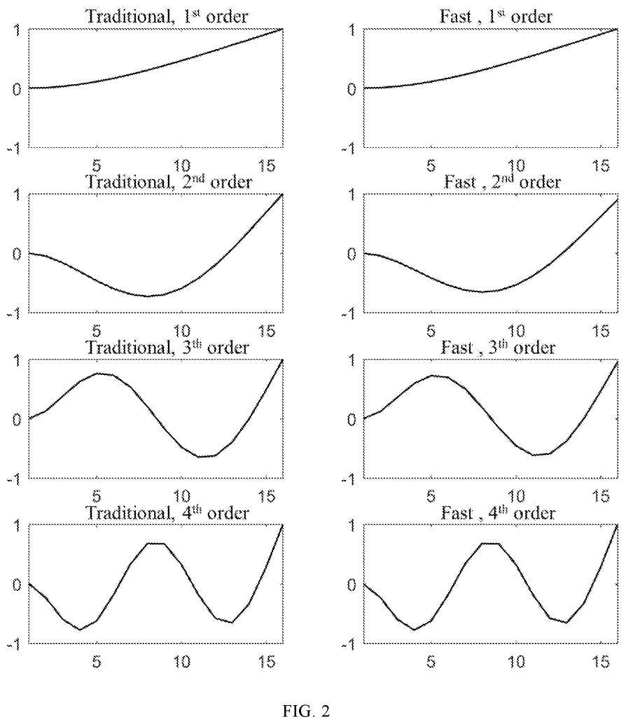

### DETAILED DESCRIPTION

For clearer objective, technical solutions and advantages, the present disclosure will be further described with reference to the accompanying drawings and examples in detail below. It should be understood that the specific examples described herein are merely illustrative of the present disclosure, should not be deemed as limiting the present disclosure.

### Example 1

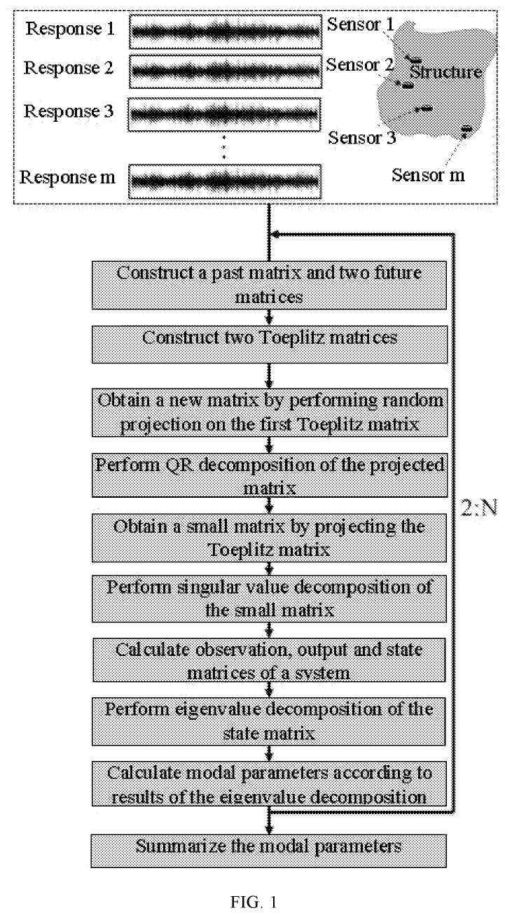

A method for identifying modal parameters of engineering structures based on fast stochastic subspace identification of the present disclosure, the flow chart of the method is shown in FIG. 1 and includes the following steps:

S1: collecting responses of a cantilever beam under stochastic excitation. The size of the cantilever beam is shown in Table 1.

TABLE 1
Parameters of the cantilever beam

| Length | Width | Height | Elastic modulus | Density | Poisson |
|---|---|---|---|---|---|
| (m) | (m) | (m) | (Pa) | (kg/m³) | ratio |
| 8 | 0.4 | 0.6 | 3E10 | 2,400 | 0.167 |

Simulating the stochastic excitation applied to the free end of the beam based on the white Gaussian noise; collecting the acceleration responses of the cantilever beam under stochastic excitation according to the sampling frequency of 500 Hz in 4 seconds; and the number of sampling channels is 16.

S2: constructing a past matrix and two future matrices. The past matrix is represented as

$${Y}_{p} = \frac{1}{\sqrt{j}} [ \begin{matrix}{y}_{0} & {y}_{1} & … & {y}_{j - 1} \\ {y}_{1} & {y}_{2} & … & {y}_{j} \\ ⋮ & ⋮ & ⋱ & ⋮ \\ {y}_{i - 1} & {y}_{i} & … & {y}_{i + j - 2}\end{matrix} ] ;$$

the future matrix 1 is represented as

$${Y}_{f 1} = \frac{1}{\sqrt{j}} [ \begin{matrix}{y}_{i} & {y}_{i + 1} & … & {y}_{i + j - 1} \\ {y}_{i + 1} & {y}_{i + 2} & … & {y}_{i + j} \\ ⋮ & ⋮ & ⋱ & ⋮ \\ {y}_{2 i - 1} & {y}_{2 i} & … & {y}_{2 i + j - 2}\end{matrix} ] ;$$

the future matrix 2 is represented as

$${Y}_{f 2} = \frac{1}{\sqrt{j}} [ \begin{matrix}{y}_{i + 1} & {y}_{i + 2} & … & {y}_{i + j} \\ {y}_{i + 2} & {y}_{i + 3} & … & {y}_{i + j + 1} \\ ⋮ & ⋮ & ⋱ & ⋮ \\ {y}_{2 i} & {y}_{2 i + 1} & … & {y}_{2 i + j - 1}\end{matrix} ] ;$$

Yᵢ represents the collected column vectors of the 16 channels; taking i as 80, J is the number of columns of the three matrices, taking 2,000−80=1,920 according to the maximum possibility.

S3: constructing two Toeplitz matrices. The Toeplitz matrix 1 is represented as T_{1|i}=[Y_{f}Yₚ^{T}], and the Toeplitz matrix 2 as T_{2|i+1}=[Y_{f2}Yₚ^{T}].

S4: obtaining a new matrix by performing random projection on the Toeplitz matrix 1. Performing random projection on the Toeplitz matrix 1 is represented as Y=T_{1|i}Ω, and Y is the new matrix; Ω is an N-dimensional Gaussian random matrix; and N represents the assumed number of orders of the structure.

S5: obtaining a unitary matrix by performing QR decomposition of the new matrix. Performing QR decomposition of the new matrix Y is represented as Y=QR, and obtaining the unitary matrix Q; and the QR decomposition here can be calculated based on the Givens.

S6: obtaining a small matrix by projecting the Toeplitz matrix 1 onto the unitary matrix of the new matrix. Projecting the Toeplitz matrix 1 onto Q to obtain the small matrix is represented as G=Q^{T}T_{1|i}, and B is the small matrix;

S7: performing singular value decomposition of the small matrix. Performing singular value decomposition of the small matrix B is represented as B=U_{B}SV^{T} and U=QU_{B} thereby obtaining U, S, V matrices.

S8: calculating observation, output and state matrices. The observation, output and state matrices are calculated according to the following formulas: O=U₁S₁^{1/2}, C=S₁^{1/2}V₁^{T} and A=S₁^{-1/2}U₁^{T}T_{2|i+1}V₁S₁^{-1/2}, where O represents the observation matrix, C represents the output matrix and and A represents the state matrix; and U₁, S₁, V₁ are the first 1−N parts of the U, S, V matrices respectively.

S9: performing eigenvalue decomposition of the state matrix of the structure. Performing eigenvalue decomposition of the state matrix of the structure is represented as A=φRφ⁻¹, thereby obtaining an eigenvector φ and a diagonal matrix R.

S10: calculating modal parameters according to results of eigenvalue decomposition. Calculating the modal parameters according to the results of eigenvalue decomposition is represented as λ_{S}^{C}=ln(λ_{S})/Δt, fₛ=|λ_{S}^{C}|/2π, ξ_{S}=|Re(λ_{S}^{C})|/|λ_{S}^{C}| and ϕ=Cϕ, where f_{S}, ξₛ and ϕ are frequency, damping ratio and mode shapes in the Sₜₕ order of the engineering structure respectively of the structure respectively. Re represents a real part; λₛ is the Sₜₕ value on the diagonal line in the diagonal matrix R; and Δt is sampling intervals of the responses.

S11: assuming that the order of the structures is within the range of 10-80, repeating the process of S2-S10 to summarize the modal parameters. The obtained modal parameters are shown in Table 2:

TABLE 2
Identified modal parameters

| | |
|---|---|
| Traditional stochastic | Fast stochastic |
| subspace identification | subspace identification |

| | Frequency | Damping | Frequency | Damping |
|---|---|---|---|---|
| Order | (Hz) | ratio (%) | (Hz) | ratio (%) |
| 1 | 3.881 | 1.452 | 3.645 | 1.956 |
| 2 | 24.054 | 1.368 | 23.910 | 1.332 |
| 3 | 62.734 | 0.923 | 62.430 | 0.922 |
| 4 | 108.210 | 1.053 | 107.900 | 0.881 |

To highlight the beneficial effect of the present disclosure, the computation time of the traditional stochastic subspace and the fast stochastic subspace in different data lengths is summarized according to the order of 10-80, as shown in Table 3, unit: second. It can be seen that the computation time of the fast stochastic subspace is shorter than that of the traditional stochastic subspace, especially when the number of rows increases, the effect of speed-up is more prominent.

TABLE 3
The computation time

| Data | | | | | | | | |
|---|---|---|---|---|---|---|---|---|
| length | 500 | | 1,000 | | 1,500 | | 2,000 | |
| Number | Traditional | Fast | Traditional | Fast | Traditional | Fast | Traditional | Fast |
| of rows | stochastic | stochastic | stochastic | stochastic | stochastic | stochastic | stochastic | stochastic |
| i | subspace | subspace | subspace | subspace | subspace | subspace | subspace | subspace |
| 30 | 1.6856 | 0.8633 | 2.1089 | 1.2747 | 2.8740 | 1.8060 | 3.1521 | 2.3591 |
| 40 | 2.8851 | 1.2482 | 3.7953 | 1.7854 | 4.4815 | 2.4809 | 5.4326 | 3.4688 |
| 50 | 4.4998 | 1.5114 | 5.9512 | 2.3022 | 6.9024 | 3.4085 | 8.4663 | 4.6229 |
| 60 | 8.0206 | 1.8759 | 9.7629 | 2.8187 | 12.7361 | 4.1863 | 15.2843 | 5.7837 |
| 70 | 14.3810 | 2.2935 | 21.6012 | 4.0428 | 23.5415 | 5.2023 | 27.5274 | 7.3402 |
| 80 | 28.2470 | 2.7078 | 27.9129 | 4.2742 | 31.0284 | 6.1051 | 33.9956 | 9.0937 |

The above is only preferred examples of the present disclosure and is not intended to limit the present disclosure. Any modification, equivalent substitution, improvement, etc. made within the spirit and principles of the present disclosure shall be included in the scope of protection of the present disclosure.

1. A method for identifying modal parameters of engineering structures based on fast stochastic subspace identification, comprising the following steps:
collecting responses of engineering structures under ambient excitation, and constructing a past matrix and two future matrices according to the collected responses;
constructing two Toeplitz matrices in sequence according to the past matrix and the two future matrices;
obtaining a new matrix by performing random projection on the first Toeplitz matrix; and
obtaining a unitary matrix by performing QR decomposition of the new matrix;
obtaining a small matrix by projecting the Toeplitz matrix onto the unitary matrix; and
obtaining U, S, V matrices respectively by performing singular value decomposition of the small matrix;
calculating observation, output and state matrices of the engineering structures according to the U, S, V matrices and the latter Toeplitz matrix;
performing eigenvalue decomposition of the state matrix of the engineering structures, and obtaining modal parameters through calculating according to results of the eigenvalue decomposition, observation and output matrices; and
determining an order interval of the engineering structures, and calculating the modal parameters repeatedly to obtain generated modal parameters of each order.

2. The method for identifying modal parameters of engineering structures based on fast stochastic subspace identification according to claim 1, wherein the ambient excitation comprises a load caused by the environment where the engineering structures are located; and the responses of the engineering structures under the ambient excitation comprise acceleration, velocity or displacement.

3. The method for identifying modal parameters of engineering structures based on fast stochastic subspace identification according to claim 1, wherein the constructing a past matrix and two future matrices according to the collected responses, respectively are:
the past matrix:
$${Y}_{p} = \frac{1}{\sqrt{j}} [ \begin{matrix}{y}_{0} & {y}_{1} & … & {y}_{j - 1} \\ {y}_{1} & {y}_{2} & … & {y}_{j} \\ ⋮ & ⋮ & ⋱ & ⋮ \\ {y}_{i - 1} & {y}_{i} & … & {y}_{i + j - 2}\end{matrix} ]$$
the future matrix 1:
$${Y}_{f 1} = \frac{1}{\sqrt{j}} [ \begin{matrix}{y}_{i} & {y}_{i + 1} & … & {y}_{i + j - 1} \\ {y}_{i + 1} & {y}_{i + 2} & … & {y}_{i + j} \\ ⋮ & ⋮ & ⋱ & ⋮ \\ {y}_{2 i - 1} & {y}_{2 i} & … & {y}_{2 i + j - 2}\end{matrix} ]$$
the future matrix 2:
$${Y}_{f 2} = \frac{1}{\sqrt{j}} [ \begin{matrix}{y}_{i + 1} & {y}_{i + 2} & … & {y}_{i + j} \\ {y}_{i + 2} & {y}_{i + 3} & … & {y}_{i + j + 1} \\ ⋮ & ⋮ & ⋱ & ⋮ \\ {y}_{2 i} & {y}_{2 i + 1} & … & {y}_{2 i + j - 1}\end{matrix} ]$$
wherein y represents the collected responses; i represents the number of rows of the three matrices; j represents the number of columns of the three matrices; and the size of j is not greater than the length of the collected responses.

4. The method for identifying modal parameters of engineering structures based on fast stochastic subspace identification according to claim 3, wherein the constructing two Toeplitz matrices, respectively are:
Toeplitz matrix 1:
T_{1|i}=[Y_{f}Yₚ^{T}]
Toeplitz matrix 2:
T_{2|i+1}=[Y_{f2}Yₚ^{T}].

5. The method for identifying modal parameters of engineering structures based on fast stochastic subspace identification according to claim 4, wherein the obtaining a new matrix by performing random projection on the first Toeplitz matrix, as shown in the following formula:
Y=T_{1|i}Ω
wherein Y is the new matrix; and Ω is an N-dimensional Gaussian random matrix.

6. The method for identifying modal parameters of engineering structures based on fast stochastic subspace identification according to claim 5, wherein the obtaining a unitary matrix by performing QR decomposition of the new matrix, comprising the following steps:
performing QR decomposition of the new matrix Y:
Y=QR
obtaining the unitary matrix Q according to the above formula; and
wherein the QR decomposition is carried out based on a Schmidt orthogonalization algorithm, a Givens algorithm or a Householder algorithm.

7. The method for identifying modal parameters of engineering structures based on fast stochastic subspace identification according to claim 6, wherein the obtaining a small matrix by projecting the Toeplitz matrix onto the unitary matrix, as shown in the following formula:
B=Q^{T}T_{1|i}
wherein B represents the small matrix;
the performing singular value decomposition of the small matrix is shown as follows:
B=U_{B}SV^{T}
U=QU_{B}
obtaining the U, S, V matrices respectively according to the above formulas.

8. The method for identifying modal parameters of engineering structures based on fast stochastic subspace identification according to claim 7, wherein the observation, output and state matrices are shown in the following formulas:
O=U₁S₁^{1/2}
C=s₁^{1/2}v₁^{T}
A=s₁^{-1/2}u₁^{T}T_{2|i+1}v₁s₁^{-1/2}
wherein O represents the observation matrix of the structure, C represents the output matrix of the structure, and A represents the state matrix of the structure; and U₁, S₁, V₁ are the first 1−N parts of the U, S, V matrices respectively.

9. The method for identifying modal parameters of engineering structures based on fast stochastic subspace identification according to claim 8, wherein the performing eigenvalue decomposition of the state matrix of the engineering structures is shown in the following formula:
A=φRφ⁻¹
obtaining an eigenvector and a diagonal matrix R according to the above formula.

10. The method for identifying modal parameters of engineering structures based on fast stochastic subspace identification according to claim 9, wherein the calculating the modal parameters is shown in the following formulas:
λ_{S}^{C}=ln(λ_{S})/Δt
f_{S}=|λ_{S}^{C}|/2π
ξₛ=|Re(λ_{S}^{C})|/|λ_{S}^{C}|

ϕ=C_{ϕ}
wherein f_{S}, ξ_{S}, and ϕ are frequency, damping ratio and mode shapes in the Sₜₕ order of the engineering structure respectively of the engineering structure respectively; Re represents a real part; λₛ is the Sₜₙ value on the diagonal line in the diagonal matrix R; and Δt is sampling intervals of the responses.
